(19) United States
(12) Patent Application Publication
(10) Pub. No.: US 2022/0115558 A1
(43) Pub. Date: Apr. 14, 2022

(54) OPTOELECTRONIC SEMICONDUCTOR DEVICE

(71) Applicant: OSRAM Opto Semiconductors GmbH, Regensburg (DE)

(72) Inventors: Michael VOELKL, Regensburg (DE); Siegfried HERRMANN, Neukirchen (DE)

(21) Appl. No.: 17/414,366

(22) PCT Filed: Dec. 16, 2019
(86) PCT No.: PCT/EP2019/085324

§ 371 Date: Jun. 16, 2021

(30) Foreign Application Priority Data
Dec. 18, 2018 (DE) 102018132651.3

(51) Int. Cl. H01L 33/10; H01L 33/62; H01L 27/15; H01L 33/32

(52) U.S. Cl. CPC H01L 33/10; H01L 33/32; H01L 27/156; H01L 33/62

(57) ABSTRACT

An optoelectronic semiconductor component may include an emitter unit and a reflector. The emitter unit may include a semiconductor layer sequence having two opposing main sides, multiple lateral surfaces, and an active zone for generating radiation. The emitter unit may include electrical contact surfaces located on the main sides. The reflector may cover the main sides and all lateral surfaces apart from up to at least 90% of a single lateral surface designed for radiation emission.

### CROSS-REFERENCE TO RELATED APPLICATIONS

The present application is a national stage entry according to 35 U.S.C. § 371 of PCT Application No. PCT/EP2019/085324 filed on Dec. 16, 2019; which claims priority to German Patent Application Serial No. 10 2018 132 651.3 filed on Dec. 18, 2018; all of which are incorporated herein by reference in their entirety and for all purposes.

### TECHNICAL FIELD

An optoelectronic semiconductor device is specified.

### BACKGROUND

A task to be solved is to specify an optoelectronic semiconductor device that emits light with a high luminance.

### SUMMARY

According to at least one embodiment, the semiconductor device comprises one or more emitter units. The at least one emitter unit is configured to emit radiation, in particular visible light, during operation of the optoelectronic semiconductor device. Alternatively or in addition to visible light, near-ultraviolet radiation and/or near-infrared radiation may also be generated by at least one emitter unit.

According to at least one embodiment, the emitter unit comprises a semiconductor layer sequence. The semiconductor layer sequence comprises two mutually opposing main sides. The main sides are the largest sides of the semiconductor layer sequence. In particular, the main sides are oriented perpendicular to a growth direction of the semiconductor layer sequence.

According to at least one embodiment, the semiconductor layer sequence comprises a plurality of side surfaces. The side surfaces are oriented transverse to the main sides. In a non-limiting embodiment, the side surfaces are parallel or approximately parallel to the growth direction of the semiconductor layer sequence. Approximately means, for example, an angular tolerance of at most 15° or 10° or 5°.

According to at least one embodiment, the semiconductor layer sequence comprises one or more active zones. The at least one active zone is configured to generate radiation. The active zone includes at least one pn junction, single quantum well structure or multiple quantum well structure. Radiation is generated in the active zone via charge carrier recombination and thus via electroluminescence. The active zone is located between an n-type region and a p-type region of the semiconductor layer sequence.

The generated radiation is an incoherent radiation and not a laser light. Thus, the emitter unit is in particular a light emitting diode chip and/or a light emitting diode unit.

The semiconductor layer sequence is based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ, wherein in each case 0≤n≤1, 0≤m≤1 and n+m≤1 as well as 0≤k<1. In particular, for at least one layer or for all layers of the semiconductor layer sequence, 0<n≤0.8, 0.4≤m<1 and n+m≤0.95 as well as 0<k≤0.5. In this context, the semiconductor layer sequence may comprise dopants as well as additional components. For simplicity, however, only the essential constituents of the crystal lattice of the semiconductor layer sequence, i.e. Al, As, Ga, In, N or P, are specified, even if these may be partially replaced and/or supplemented by small amounts of additional substances.

According to at least one embodiment, the emitter unit comprises electrical contact surfaces, such as exactly two electrical contact surfaces. The electrical contact surfaces are configured for current injection into the semiconductor layer sequence. The electrical contact surfaces are located on the main sides of the semiconductor layer sequence.

According to at least one embodiment, the semiconductor device comprises a reflector. The reflector may be an integral part of the at least one emitter unit. The reflector predominantly covers the main sides and all side surfaces of the semiconductor layer sequence except for a single side surface configured for radiation emission. Predominantly means to at least 70% or 90%.

The main sides and the side surfaces not configured for radiation emission may also be completely covered by the reflector. The reflector is configured to reflect radiation generated during operation. A reflectance of the reflector for this radiation is at least 80% or 90% or 96% or 98%. The reflector may be made of one piece. In a non-limiting embodiment, however, the reflector is multi-piece and composed of multiple components.

In at least one embodiment, the optoelectronic semiconductor device comprises at least one emitter unit and at least one reflector. The emitter unit comprises a semiconductor layer sequence comprising two opposing main sides, a plurality of side surfaces, and an active zone for generating radiation. The emitter unit includes electrical contact surfaces located on the main sides. The reflector covers at least 90% of the main sides and all side surfaces except for a single side surface set up for radiant emission.

For many applications, for example for headlights in motor vehicles or in projectors, high luminance densities are required. With the semiconductor device described herein, high luminance levels are achievable, wherein the semiconductor device comprises small geometric dimensions.

In particular, in the semiconductor device described herein, the generated light is coupled out at a single facet or side surface. The semiconductor layer sequence may be designed as an optical waveguide to transport light generated far away from the outcoupling surface of the semiconductor layer sequence to the outcoupling surface. In a non-limiting embodiment, the outcoupling surface is very small to achieve high luminance densities.

A metallic mirror coating of a growth top side and a growth bottom side can be used as a full area p-contact surface and as an n-contact surface. High light extraction efficiency can be achieved via a suitable geometry of the semiconductor layer sequence.

A pixelated imaging system may be constructed in which each emitter unit may be controlled separately. This allows high-resolution imaging with high luminance to be achieved. It is possible to have geometric out coupling structures at the out coupling side.

A combination with optical systems and converters, i.e. phosphors, at the outcoupling side is possible, especially along an emission direction. Different variants of a mirroring of the semiconductor layer sequence, a contact guidance and an electrical insulation are possible. Geometric modifications of the contact surfaces and/or a cross-sectional area or base surface of the semiconductor layer sequence can be used to achieve further increased luminance densities.

For example, compared to a conventional semiconductor device of the same size, the semiconductor device comprises a radiation density increased by a factor of 6 on the output side configured for radiation emission.

With the emitter units, arrays may be built up which can be electrically connected in series by means of a full-area stacking on top of each other at the electrical contact surfaces. The emitter units can also be electrically connected in parallel by placing the contact surfaces next to each other. Combinations are possible in this context. Such arrays may replace conventional LED chips and are suitable for headlights, projection applications, street lighting and/or general lighting. Thereby, an emission in the visible spectral range may take place, for example blue, green and/or red light or also white light can be emitted or an emission in the ultraviolet spectral range and/or in the infrared spectral range takes place.

In particular, an application of the emitter units as well as the semiconductor device in mini-projectors and near-to-eye applications is possible.

Due to their particularly small thickness, individual emitter units are well suited for special applications, for example for coupling into thin, rectangular or also ellipsoidal fibers or optical waveguides.

Power loss during electro-optical conversion can be dissipated, for example, by means of air flow, liquid cooling or a heat sink.

According to at least one embodiment, the contact surfaces cover the main surfaces predominantly in each case, for example at least 70% or 90% or 95% or completely. The contact surfaces are a part of the reflector.

According to at least one embodiment, the contact surfaces each comprise at least one metallic layer. Optionally, the contact surfaces comprise a further layer, in particular a layer of a transparent conductive oxide, TCO for short, such as ITO or such as zinc oxide. Such a TCO contact layer is located between the metallic layer and the semiconductor layer sequence.

The metallic layer or the TCO layer of the contact surfaces is a continuous, gapless and contiguous layer. Alternatively, the metallic layer or the TCO layer may be structured. Between, for example, island-shaped regions of the metallic layer or the TCO layer, there may be a dielectric mirror or a combination mirror with metallic and with dielectric components.

According to at least one embodiment, a maximum distance of the reflector to the semiconductor layer sequence is at most 10 μm or 5 μm or 2 μm or 1 μm. In particular, the reflector is located directly on the semiconductor layer sequence in places or over the entire surface. For example, only a passivation layer is located in places between the semiconductor layer sequence and the reflector.

According to at least one embodiment, the side surface configured for radiation emission is predominantly or entirely free of the reflector. For example, this side surface is covered by the reflector to at most 5% or 10% or 20% or not at all.

According to at least one embodiment, a total thickness of the emitter unit is at most four times or three times or twice a thickness of the n-type region or n-type regions of the semiconductor layer sequence. In other words, the overall thickness of the emitter units is substantially determined by the semiconductor layer sequence. A thickness of the contact surfaces and the reflector in particular is smaller than the thickness of the semiconductor layer sequence. For example, a thickness of each contact surface is at most 10% or 20% or 40% of the thickness of the n-type region or n-type regions of the semiconductor layer sequence.

According to at least one embodiment, the side surface configured for radiation emission is provided with a roughening. Via such a roughening, an increased light extraction efficiency can be achieved. In a non-limiting embodiment, such a roughening is present exclusively on the side surface configured for radiation emission.

According to at least one embodiment, the semiconductor device comprises a plurality of the emitter units. A collective emission surface is formed by the emitter units, which is composed of the side surfaces of the emitter units configured for radiation emission. The emission surface may be a flat, planar surface.

Each of the emitter units may comprise its own reflector. Alternatively, a common reflector is present for all emitter units or each for a group of emitter units. In a non-limiting embodiment, the contact surfaces each form a part of the reflector between two adjacent emitter units. Alternatively, the contact surfaces are not part of the reflector and do not reflect or do not reflect significantly, for example in the case of TCO contact surfaces with a refractive index similar to the refractive index of the semiconductor layer sequence.

If the emitter units each comprise multiple active zones, tunnel contacts may be provided between adjacent active zones. In a non-limiting embodiment, however, the emitter units each comprise only exactly one active zone.

According to at least one embodiment, the emitter units are present in a linear or in a two-dimensional arrangement. That is, the side surfaces configured for radiation emission can all be arranged along an in particular straight line. Alternatively, in the case of a two-dimensional arrangement, the side surfaces configured for radiation emission are arranged in a regular, for example rectangular, grid as seen in a plan view of these side surfaces.

According to at least one embodiment, adjacent emitter units are arranged successively at their main surfaces, in particular arranged directly stacked on top of each other. Alternatively or additionally, an arrangement of adjacent emitter units can be made over side surfaces, in particular over opposite side surfaces which are not configured for radiation emission. If an arrangement of successive emitter units is present only over opposite side surfaces, a very thin semiconductor device may be produced which is suitable, for example, for display backlighting or for coupling into optical fibers or optical fiber plates.

According to at least one embodiment, at least some of the emitter units are directly mechanically and electrically connected to each other via their contact surfaces. For example, the respective emitter units are soldered or electrically conductively bonded to each other, so that there is only one bonding means between the contact surfaces of successive emitter units.

According to at least one embodiment, the emitter units or groups of emitter units can be driven electrically independently of one another. Emitter units emitting different colors are present. For example, red light emitting emitter units, green light emitting emitter units and blue light emitting emitter units are present. It is possible that pixels are formed by the emitter units, so that the semiconductor device can be a display device.

According to at least one embodiment, a number of emitter units of the semiconductor device is at least 100 or 300 or 1000. Alternatively or additionally, the number of emitter units is at most 100,000 or 30,000 or 10,000. Thus, it is possible that the semiconductor device has relatively few emitter units compared to a display, which typically comprise a high resolution with millions of pixels.

According to at least one embodiment, a thickness of the semiconductor layer sequence between the main sides is at least 0.5 μm or 1 μm or 2 μm. Alternatively or additionally, this thickness is at most 12 μm or 6 μm or 4 μm.

According to at least one embodiment, the semiconductor layer sequence comprises a length of at least 10 μm or 40 μm or 150 μm in a direction perpendicular to the side surface configured for radiation emission. Alternatively or additionally, this length is at most 0.5 mm or 200 μm or 100 μm.

According to at least one embodiment, the semiconductor layer sequence comprises a width of at least 30 μm or 50 μm or 100 μm in a direction transverse or parallel to the side surface configured for radiation emission. Alternatively or additionally, this width is at most 1 mm or 0.5 mm or 250 μm.

According to at least one embodiment, the width of the semiconductor layer sequence is greater than the length of the semiconductor layer sequence, or vice versa. For example, the width exceeds the length by at least a factor of 1.5 or 3 or 10, or vice versa.

According to at least one embodiment, the reflector comprises or consists of one or more metal layers. If several metal layers of the reflector are present, these metal layers may be arranged next to each other and thus not overlapping. Alternatively, multiple metal layers may follow one another in the direction away from the semiconductor layer sequence. If the reflector comprises exclusively metal layers, the reflector is a metallic reflector.

According to at least one embodiment, the reflector comprises at least one total internal reflection layer. The total internal reflection layer comprises a relatively low refractive index for radiation generated during operation compared to the semiconductor layer sequence. For example, such a total internal reflection layer is made of an oxide such as silicon dioxide or of a nitride such as aluminum nitride. The reflector may comprise a plurality of such layers, which may be arranged side by side or stacked on top of each other.

According to at least one embodiment, the reflector is at least in part a Bragg reflector. The reflector then comprises a plurality of radiation-transmissive layers with alternating high and low refractive indices. A reflective metal layer may be located on a side of the Bragg reflector facing away from the semiconductor layer sequence, so that the Bragg reflector need be formed from fewer layer pairs.

As an alternative to specular reflectors such as metal reflectors or Bragg reflectors, diffuse reflectors can also be used. For example, the reflector is then formed by a transparent matrix material in which particles with a different refractive index are embedded. In particular, the reflector in this case is made of a silicone with titanium dioxide particles added. The reflector may appear white.

Different types of reflectors may be present on different sides of the semiconductor layer sequence. For example, on the main sides metallic reflectors are provided in form of the contact surfaces, whereas on the side surfaces not configured for radiation emission the reflector may be formed by a Bragg mirror or by a diffuse reflective layer, or alternatively by a combination mirror, for example with the metallic layer and with a total internal reflection layer.

According to at least one embodiment, the reflector comprises at least one side part located on the side surfaces of the semiconductor layer sequence not configured for radiation emission. The at least one side part is made of an electrically conductive material and may be formed by the metal layer or by a part of the metal layer.

According to at least one embodiment, the at least one side part is electrically separated from the contact surfaces. Alternatively, the at least one side part is electrically connected with one of the contact surfaces, in particular ohmically conductively electrically connected. In the latter case, the side part is, for example, a part of the contact surface at the n-type region of the semiconductor layer sequence or a part of the contact surface at the p-type region of the semiconductor layer sequence. With other words, one of the contact surfaces may extend to the side regions of the semiconductor layer sequence not intended for radiation emission.

According to at least one embodiment, an electrical insulation layer, in particular only one electrical insulation layer, is located between the active zone and the reflector. This electrical insulation layer can form a part of the reflector, in particular a layer of a Bragg mirror or the total internal reflection layer of a combination mirror. By means of such an electrical insulation layer covering the active zone and the n-type region and/or the p-type region, short circuits due to metallic components of the contact surfaces and/or the reflector can be avoided.

According to at least one embodiment, the semiconductor device comprises one or more phosphors. The at least one phosphor is disposed at least or only on or over the side surface configured for emitting radiation. That is, the phosphor may be located directly on said side surface. The phosphor is embedded in a matrix material, such as a glass or a plastic, such as a silicone. Alternatively, the phosphor may be a ceramic such as a sintered ceramic.

According to at least one embodiment, the semiconductor layer sequence is configured to generate blue light. In this case, the semiconductor layer sequence is based on the AlInGaN material system.

It is possible that different phosphors are arranged downstream of different emitter units. Thus, the emitter units may all be based on the same material system, in particular on AlInGaN, and still be configured to generate light of different colors with the help of the at least one phosphor. Alternatively, different semiconductor materials are used to generate different colors.

According to at least one embodiment, the semiconductor layer sequence or the semiconductor layer sequence together with the contact surfaces is configured as an optical waveguide towards the side surface which is configured for radiation emission. Thus, the semiconductor layer sequence, which generates incoherent radiation, alone or the semiconductor layer sequence together with the contact surfaces can comprise cladding layers which exhibit a comparatively low refractive index. Thus, a totally reflecting, waveguiding structure similar to a two-dimensional optical waveguide may be formed in the semiconductor layer sequence.

According to at least one embodiment, the semiconductor layer sequence tapers in a direction towards the side surface configured for radiation emission. This is true when viewed in a plan view of one of the main sides and/or in cross-section through the main sides. That is, viewed in a plan view of the main sides, the semiconductor layer sequence may narrow toward the radiation emitting side. Alternatively or additionally, a thickness of the semiconductor layer sequence may decrease toward the radiation emitting side.

Furthermore, an illumination system is specified. Features of the illumination system are disclosed for the semiconductor device and vice versa. The illumination system comprises one or more of the optoelectronic semiconductor devices and an imaging unit, in particular a movable mirror. In a non-limiting embodiment, an optical system such as a converging lens is located between the semiconductor device and the mirror.

### BRIEF DESCRIPTION OF THE DRAWINGS

In the following, an optoelectronic semiconductor device described here will be explained in more detail with reference to the drawing using non-limiting embodiments. Identical reference signs specify identical elements in the individual figures. However, no references to scale are shown; rather, individual elements may be shown in exaggerated size for better understanding.

In the Figures:

FIG. 1 shows a schematic perspective view of an exemplary embodiment of an optoelectronic semiconductor device described herein,

FIG. 2 shows a schematic sectional view of an exemplary embodiment of an optoelectronic semiconductor device described herein,

FIG. 3 shows a schematic sectional view of a modification of a semiconductor device,

FIG. 4 shows a schematic sectional view of an exemplary embodiment of an optoelectronic semiconductor device described herein,

FIG. 5 shows a schematic perspective view of an exemplary embodiment of an optoelectronic semiconductor device described herein,

FIG. 6 shows a tabular overview of exemplary embodiments and of a modification of semiconductor devices,

FIGS. 7 to 11 show schematic plan views of an outcoupling side of exemplary embodiments of optoelectronic semiconductor devices described herein,

FIGS. 12 to 14 show schematic sectional views of exemplary embodiments of optoelectronic semiconductor devices described herein,

FIGS. 15 and 16 show schematic plan views of exemplary embodiments of optoelectronic semiconductor devices described herein,

FIG. 17 shows a schematic plan view of an emission surface of an exemplary embodiment of an optoelectronic semiconductor device described herein,

FIG. 18 shows a schematic sectional view of an exemplary embodiment of an optoelectronic semiconductor device described herein,

FIG. 19 shows a schematic perspective view of an exemplary embodiment of an optoelectronic semiconductor device described herein,

FIGS. 20 and 21 show schematic sectional views of exemplary embodiments of optoelectronic semiconductor devices described herein,

FIG. 22 shows a schematic sectional view and FIG. 23 shows a schematic plan view of an exemplary embodiment of an optoelectronic semiconductor device described herein,

FIG. 24 shows a schematic plan view and FIG. 25 shows a schematic sectional view along the dot-dash line of FIG. 24 of an exemplary embodiment of an optoelectronic semiconductor device described herein, and

FIG. 26 shows a schematic perspective view of an exemplary embodiment of a illumination system with an optoelectronic semiconductor device described herein.

### DETAILED DESCRIPTION

FIG. 1 shows an exemplary embodiment of an optoelectronic semiconductor device 10. The semiconductor device 10 is formed by a single emitter unit 1.

The emitter unit 1 comprises a semiconductor layer sequence 2. The semiconductor layer sequence 2 includes an active zone 22 located between an n-type region 21 and a p-type region 23. In a non-limiting embodiment, the semiconductor layer sequence 2 is based on the AlInGaN material system. That is, the layers 21, 23 may each be appropriately doped GaN layers.

Furthermore, the emitter unit 1 comprises electrical contact surfaces 31, 32. A first electrical contact surface 31 is located at the n-type region 21, a second electrical contact surface 32 is located at the p-type region 23. The contact surfaces 31, 32 are metallic layers or metallic layer stacks. Thus, the contact surfaces 31, 32 are located at main sides 24, 25 of the semiconductor layer sequence 2, directly at the main sides 24, 25.

The contact surfaces 31, 32 constitute parts of a reflector 4 for radiation generated during operation. Furthermore, the reflector 4 extends on three side surfaces 26 and completely or almost completely covers these side surfaces 26. The cuboidal semiconductor layer sequence 2 is thus surrounded by the reflector 4 on five of six side surfaces 26, so that no radiation or no significant portion of radiation exits from the emitter unit 1 at these side surfaces 26 during operation.

A single side surface 27 is formed as an emission surface 11 of the emitter unit 1. Only at this side surface 27 radiation exits the semiconductor layer sequence 2 during operation. This side surface 27 may be a smallest side surface of the semiconductor layer sequence 2.

A total thickness of the emitter unit 1 is approximately equal to a thickness T of the semiconductor layer sequence 2. For example, the thickness T is between 2 μm and 5 μm inclusive. A thickness of the contact surfaces 31, 32 and/or of the reflector 4 is below 1 μm, in particular below 0.5 μm. Thus, the emitter unit 1 comprises a similar size as the semiconductor layer sequence 2 designed as a carrierless light-emitting diode chip.

A light box defined by the reflector 4 thus also comprises approximately the same size as the semiconductor layer sequence 2. Such an arrangement, which is limited to the size of the semiconductor layer sequence 2, is also referred to as a chip-scale light box.

For example, a length L of the semiconductor layer sequence 2 and thus the emitter unit 1 is between 30 μm and 100 μm inclusive. A width W of the semiconductor layer sequence 2 is, for example, at least 40 μm and/or at most 400 μm.

Corresponding values may apply to all other exemplary embodiments.

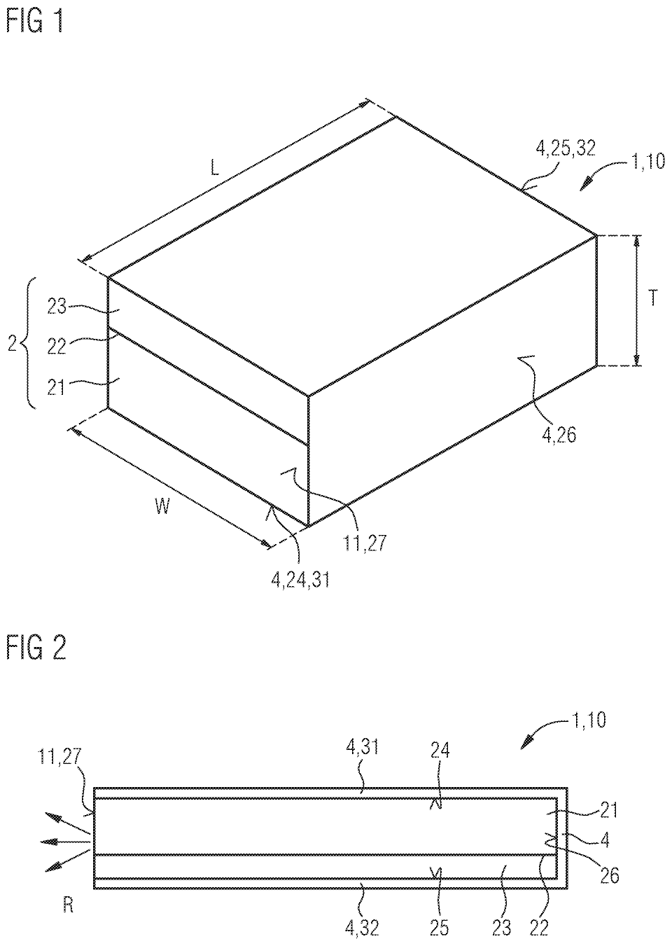

FIG. 2 illustrates a sectional view of a semiconductor device 10 formed of exactly one emitter unit 1. The semiconductor device 10 of FIG. 2 is essentially constructed in the same way as the semiconductor device 10 of FIG. 1. An emission of, for example, blue light R takes place exclusively at that side surface 27 which forms the emission surface 11.

The semiconductor device 10 thus comprises a small outcoupling surface 27, whereby a large luminance can be achieved at the emission surface 11. The comparatively long semiconductor layer sequence 2 acts as an optical waveguide in the direction toward the emission surface 11. Thus, light generated far from the emission surface 11 in the active zone 22 can still be efficiently coupled out of the semiconductor layer sequence 2.

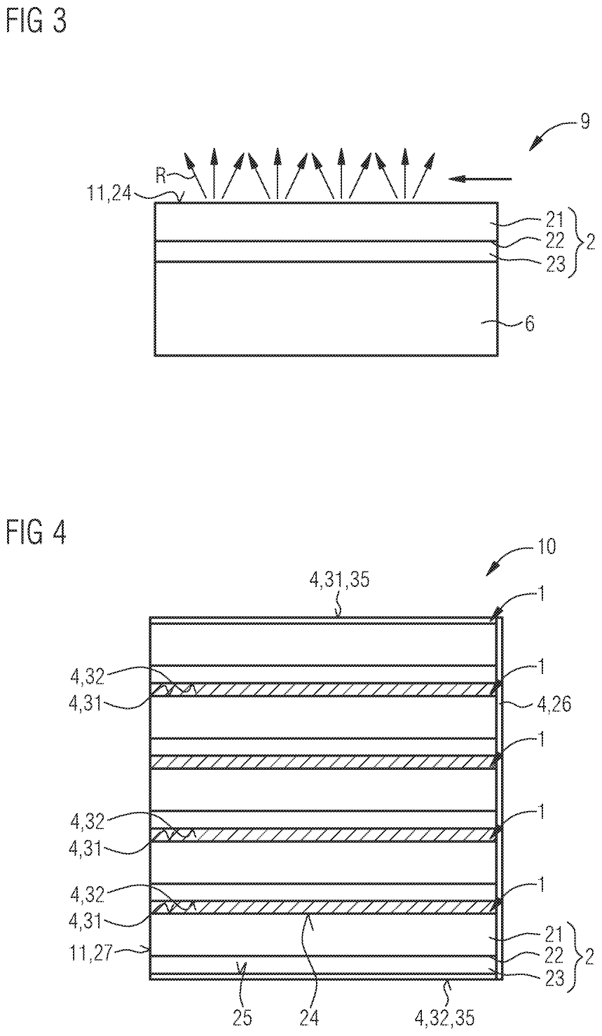

In FIG. 3, a modification 9 is shown. The modification 9 is a conventional light emitting diode chip in which the semiconductor layer sequence 2 is located on a carrier 6. The light R generated in operation is emitted mainly at a main side 24, which also forms the emission surface 11. The light emission occurs over a relatively large area, so that only comparatively low luminance levels can be achieved.

In the exemplary embodiment of the semiconductor device 10 of FIG. 4, several of the emitter units 1 are arranged stacked on top of each other. The individual emitter units 1 are connected to each other via adjacent contact surfaces 31, 32, which are attached to each other, for example, by means of soldering. Adjacent semiconductor layer sequences 2 of the emitter units 1 are separated from each other by the respective associated contact surfaces 31, 32 and a bonding means, such as a solder, which is not drawn. The individual emitter units 1 are electrically connected in series via the contact surfaces 31, 32.

Outermost contact surfaces 31, 32 are configured as contact surfaces 35 for external electrical contacting of the semiconductor device 10. These outermost contact surfaces 31, 32 are, for example, designed to be thicker and/or comprise additional metal layers, compared to the inward contact surfaces 31, 32.

The side surfaces 26, which are not configured for the emission of light, are continuously covered by the reflector 4. The side surfaces 27 of the individual emitter units 1, which are configured for emission of radiation, together form the emission surface 11. The emission surface 11 and thus all side surfaces 27, at which radiation is emitted, such as lie in one plane.

According to FIG. 4, the emitter units 1 are arranged linearly. In contrast, in FIG. 5 there is a two-dimensional arranging of the emitter units 1. Along a stack direction of the emitter units 1, the emitter units 1 can be electrically connected in series and form columns. In the direction parallel to the external contact surfaces 35, the emitter units can be electrically connected in parallel. Thus, there may be a combined parallel connection and series connection of the emitter units 1.

Between adjacent series circuits of the emitter units 1 and on outer side surfaces not covered by the external contact surfaces 35, the reflector 4 is located in each case. In addition, the reflector 4 comprises the contact surfaces 31, 32 located between adjacent emitter units 1. The reflector 4 optionally extends between adjacent columns can be formed in this region from a dielectric mirror. Side part 44 of the reflector 4 are, for example, metallic or formed of a diffusely reflecting material, such as a titanium dioxide-filled silicone.

The emitter units 1 are mounted on a carrier 6. The carrier 6 is a heat sink of the semiconductor device 10. Optionally, the carrier 6 may comprise undrawn cooling fins for air cooling. Further, the carrier 6 may comprise undrawn channels for liquid cooling.

According to FIG. 5, the emitter units 1 are all identical in construction. Deviating from the illustration of FIG. 5, emitter units of different construction can also be combined to form the semiconductor device 10. For example, red-emitting, green-emitting and blue-emitting emitter units can be combined with each other, so that RGB pixels can result.

Deviating from the illustration of FIG. 5, such RGB pixels or also the emitter units 1 as a whole can be controlled electrically independently of one another. Corresponding electrical contact surfaces or wiring levels can be integrated in the carrier 6. Likewise, the carrier 6 may comprise drive electronics 62. Thus, the carrier 6 may be an IC chip.

Deviating from the illustration in FIG. 5, the carrier 6 with the optional drive electronics 62 can also be located on side surfaces of the field with the emitter units 1. The same applies to all other exemplary embodiments.

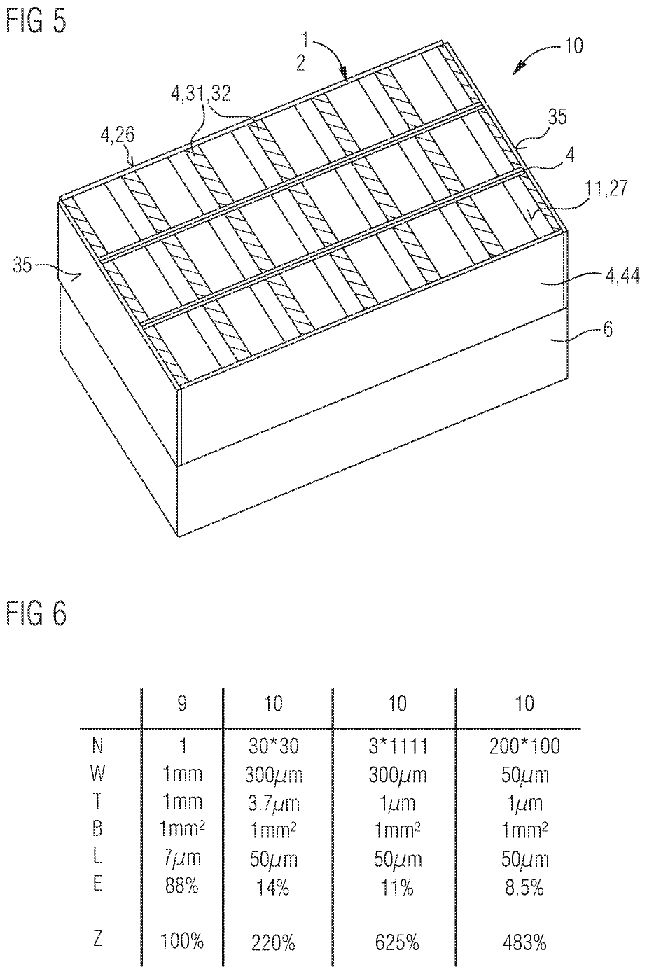

FIG. 6 specifies exemplary geometrical and optical parameters for the modification 9 of FIG. 3 and for various exemplary embodiments of the semiconductor devices 10, analogous to FIG. 5.

Specified in each case is a number N of emitter units 1, the width W of the associated semiconductor layer sequence and thus of the associated emitter units, the thickness T, a base surface B of the corresponding semiconductor device 10, the length L as well as an extraction efficiency E and a relative luminance density Z at the emission surface 11.

For example, the semiconductor device 10 comprises 30×30=900 or 3×1111=3333 or 200×100=20000 of the emitter units 1. Thus, the semiconductor device 10 may comprise a comparatively large number of emitter units 1.

Depending on the geometry of the emitter units 1 and thus the respective semiconductor layer sequence 2, different values result for an extraction efficiency E and for a relative luminance density Z. The values for the extraction efficiency E are based on a semiconductor layer sequence 2 without any roughening, so that these values can increase with an optimization of an outcoupling.

Furthermore, it can be seen from FIG. 6 that high relative luminance densities Z are achievable with the semiconductor devices 10 described here. Especially in applications where optical elements are placed downstream of the semiconductor devices 10, the higher relative luminance density Z can compensate for a possibly lower extraction efficiency E, since at a certain given brightness a smaller emission surface 11 results and an optical imaging can be made more efficient.

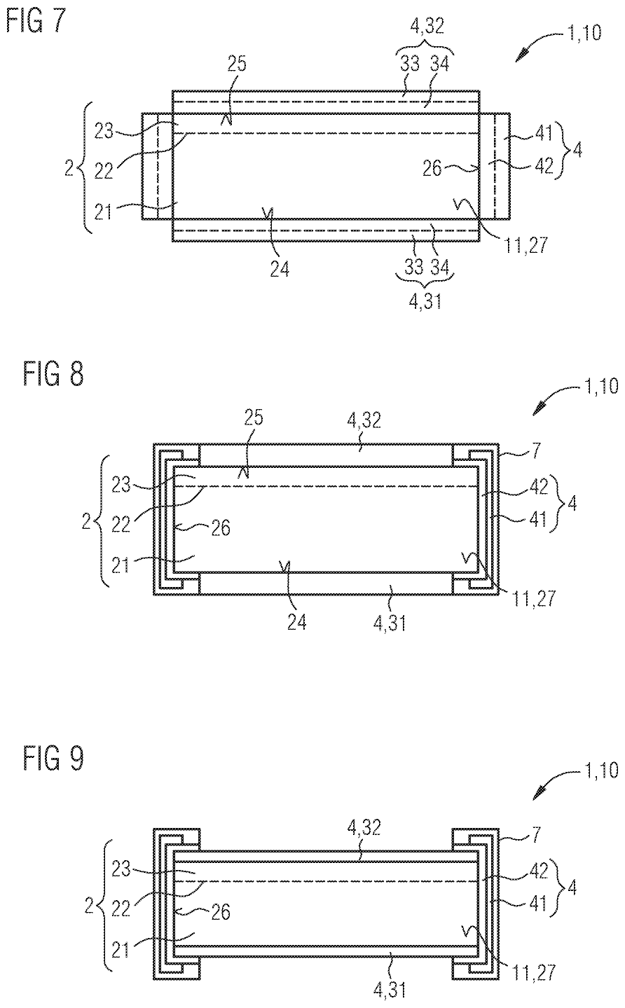

FIGS. 7 to 11 show various design options for the reflector 4 and the contact surfaces 31, 32. These respective embodiments can be used accordingly in all exemplary embodiments.

According to FIG. 7, the contact surfaces 31, 32 each comprise a layer 34 of a transparent conductive oxide. The layer 34 comprises a smaller refractive index than the semiconductor layer sequence 2. Thus, the layer 34 can act as a total internal reflection layer, so that a high light guiding efficiency can result in the direction towards the side surface 27, equal to the emission surface 11. In addition, the contact surfaces 31, 32 each comprise at least one metallic layer 33.

The reflector 4 at the non-emissive side surfaces 26 is constructed analogously to the contact surfaces 31, 32. Thus, the reflector 4 includes an electrical insulation layer 42 made of a low refractive index material such as silicon dioxide. In addition, the reflector 4 includes at least one metal layer 41.

Thus, total reflection of radiation can be achieved via the layers 34, 42, whereas conventional specular reflection from metals can be achieved via the layers 33, 41.

The contact surfaces 31, 32 can be flush or approximately flush with the main sides 24, 25. Accordingly, the reflector 4 may be flush or approximately flush with the respective side surfaces 26.

In the following, the contact surfaces 31, 32 are each drawn only as metallic contact surfaces. However, the layer 34 of a transparent conductive oxide can optionally be present in addition in all other exemplary embodiments.

According to FIG. 8, the contact surfaces 31, 32 only partially cover the main sides 25, 24. Instead, the insulating layer 42, viewed in cross-section, extends in a U-shape over the side surfaces 26 to the contact surfaces 31, 32. The metal layer 41 can also be U-shaped in cross-section and extend partially onto the main sides 24, 25.

Optionally, an electrically insulating passivation layer 7 is provided to encapsulate the metal layer 41 and prevent short circuits between the contact surfaces 31, 32 and the metal layer 41.

According to FIG. 9, the layers 41, 42 are U-shaped in cross-section. Deviating rom FIG. 8, the layers 41, 42 extend to the contact surfaces 31, 32, wherein short circuits are prevented by the insulation layer 42. Optionally, the passivation layer 7 is again present.

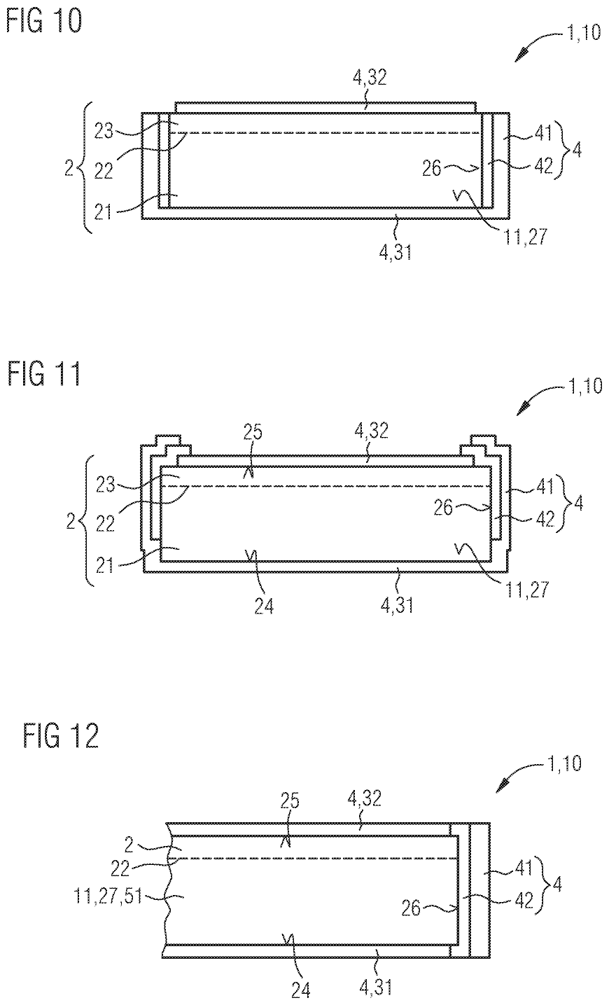

In FIGS. 7 to 9, the metal layer 41 is electrically separated from the contact surfaces 31, 32 in each case. In contrast, there is a direct, ohmically conductive electrical connection between the metal layer 41 on the side surfaces 26 and one of the contact surfaces 31 according to FIGS. 10 and 11. Here, according to FIG. 10, extensions of the first contact surface 31 cover the side surfaces 26 substantially completely. According to FIG. 11, the extensions of the contact surface 31 extend to the main side 25 with the contact surface 32.

Optionally, it is possible for these extensions for the reflector 4 to be located directly on the side surfaces 26 in places. Alternatively, the insulation layer 42 may extend to the main side 24 at the contact layer 31. Optionally, the insulation layer 42 may extend to the contact surface 32.

In FIG. 12, it is illustrated that the emission surface 11, and thus the side surface 27 which is configured for radiation emission, is provided with a roughening 51. Via such a roughening 51, an increased light extraction efficiency can be achieved. In a non-limiting embodiment, such a roughening 51 is also present in all exemplary embodiments.

Furthermore, it is illustrated in FIG. 12 that the reflector 4, for example a white, diffusely reflecting material, can be flush or approximately flush with the contact surfaces 31, 32 at the rear side surface 26 in a direction perpendicular to the active zone 22. The same may apply to the insulating layer 42.

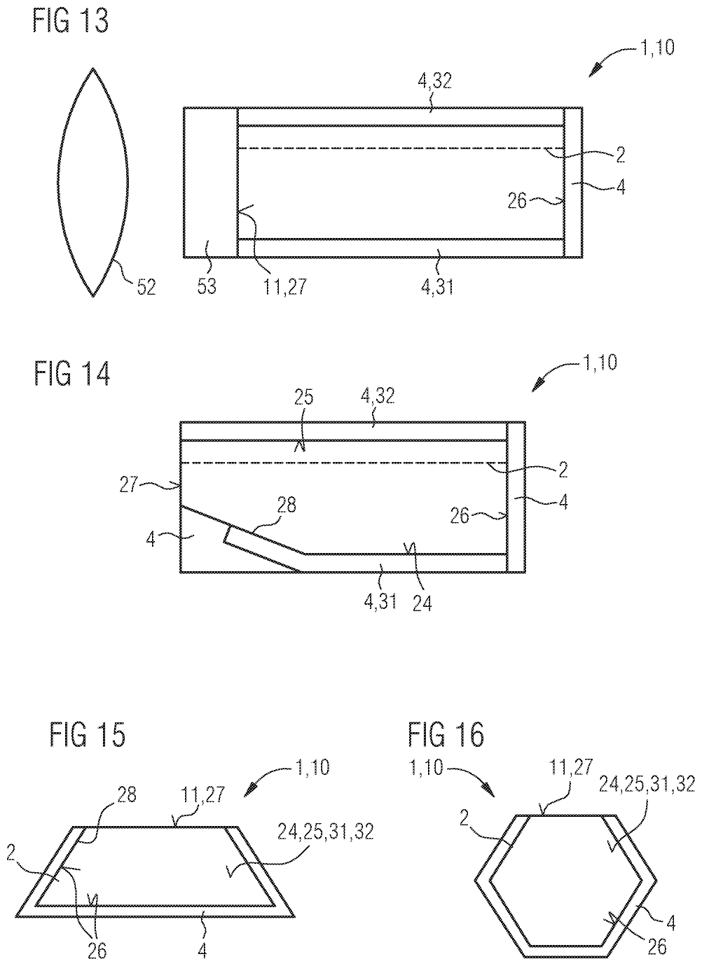

In the exemplary embodiment of FIG. 13, at least one phosphor 53 is located at the emission surface 11. Via the phosphor 53, a partial or complete conversion of the radiation generated in the semiconductor layer sequence 2 into radiation of a different wavelength can take place. For example, yellow light can be partially generated from blue light, so that white light is emitted overall.

Alternatively, individual emitter units 1 may use phosphors to separately generate green light and red light. For example, in the embodiment of FIG. 5, different phosphors may be applied to the respective emitter units 1 to obtain RGB pixels.

Optionally, an optics 52 is arranged downstream of the semiconductor device 10, for example for light imaging. Since a comparatively high luminance density is emitted at the emission surface 11, the emission surface 11 may be comparatively small, which may result in increased quality and efficiency of an optical image.

In the exemplary embodiment of FIG. 14, it is illustrated that the semiconductor layer sequence 2 becomes thinner in a region of a taper 28 toward the side surface 27 which is configured for radiation emission. Thus, an even smaller side surface 27 can be achieved, accompanied by higher luminance densities.

It is possible that the contact surface 31 on the side where the taper 28 is located does not extend to the side surface 27. A remaining region of the main side 24 near the side surface 27 may be covered by the reflector 4, wherein planarization is possible by means of the reflector 4.

FIGS. 13 and 14 further illustrate that the reflector 4, at least at the side surfaces 26, may be a Bragg reflector, in particular made of dielectric materials, or an electrically insulating, diffusely reflecting material. Thus, no additional electrically insulating layers need to be applied to the side surfaces 26.

In the plan view of FIG. 15 it is shown that the semiconductor layer sequence 2 can be trapezoidal in shape. Thus, a width of the semiconductor layer sequence 2 may decrease in a direction toward the emission surface 11.

In FIG. 16, it is illustrated that the semiconductor layer sequence 2 has a hexagonal shape rather than a square shape when viewed in a plan view. Also in this case, a width of the semiconductor layer sequence 2 decreases toward the emission surface 11. The reflector 4 again covers all side surfaces 26 except for exactly one side surface 27 configured for emission.

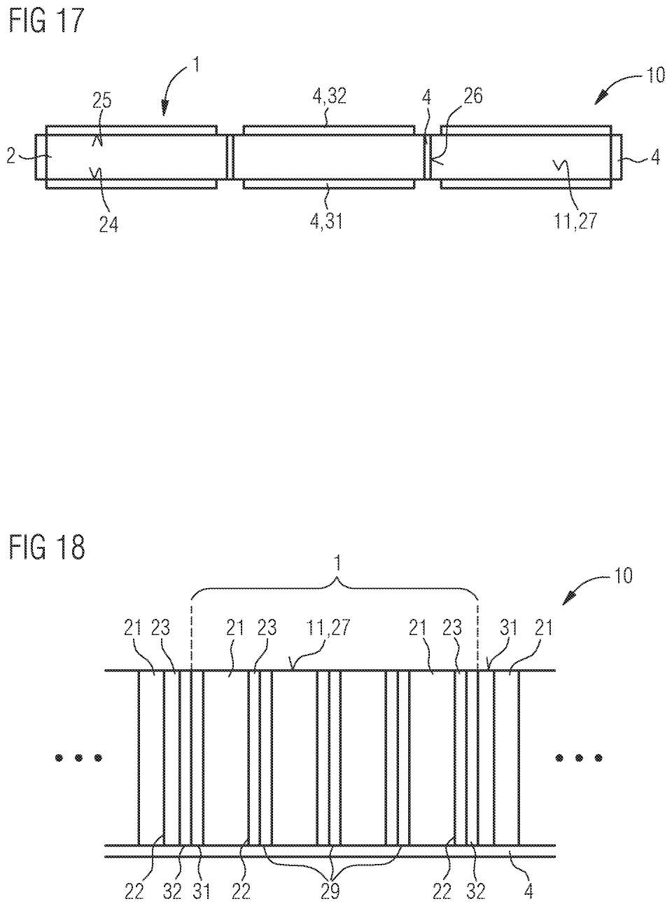

In the exemplary embodiment of FIG. 17, it is shown that several of the emitter units 1 are arranged next to each other on the side surfaces 27. The main sides 24, 25 and thus the contact surfaces 31, 32 can thus be freely accessible. With such an arrangement, a particularly thin semiconductor device 10 can be realized. Optionally, a carrier, which is not drawn, is provided to mechanically stabilize the arrangement of the emitter units 1.

According to FIG. 18, the emitter unit 1 comprises a plurality of active zones 22 and also a plurality of the n-type regions 21 and the p-type regions 23 which sandwich the respective active zone 22. Tunnel junctions 29 are located between adjacent cells of the emitter unit 1. All of the regions 21, 22, 23, 29 of the emitter unit 1 may be contiguously epitaxially grown.

Several such emitter units 1 may be stacked on top of each other. The emitter units 1 each comprise contact surfaces 31, 32 at their edges, which are designed as part of the reflector 4.

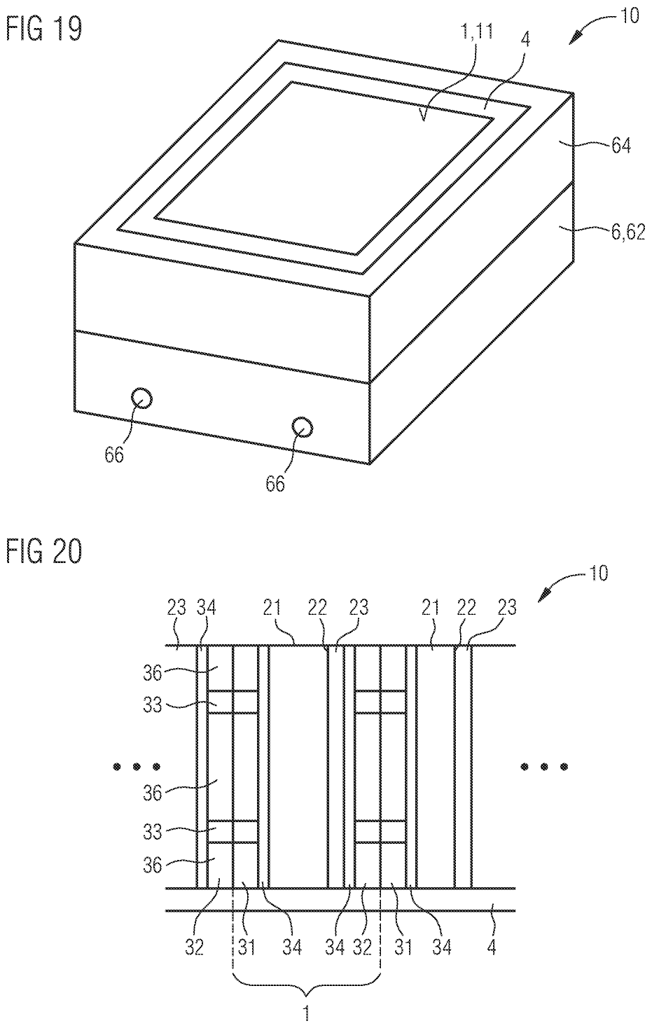

In the exemplary embodiment of FIG. 19, the array of emitter units 11 forming the emission surface 11 is surrounded all around by the reflector 4. In this case, the reflector 4 is made of a transparent matrix material with reflective particles.

For more efficient cooling, the thin reflector 4 is surrounded all around on the outside by a cooling body 64. The cooling body 64 is for example galvanically generated. Cooling components 66 may be present in the carrier 6, for example cooling channels for liquids or gases or thermoelectric components.

In FIG. 20 it is illustrated that the contact surfaces 31, 32 are structured. Thus, the contact surfaces 31, 32 each comprise several of the metallic layers 33 which are embedded in an intermediate layer 36. The intermediate layer 36 may be of an electrically insulating or electrically conductive material, such as a material that is transparent to the generated radiation. Optionally, TCO contact layers 34 are provided. Such designed contact surfaces 31, 32, 33, 34, 36 can be used in all other exemplary embodiments as well.

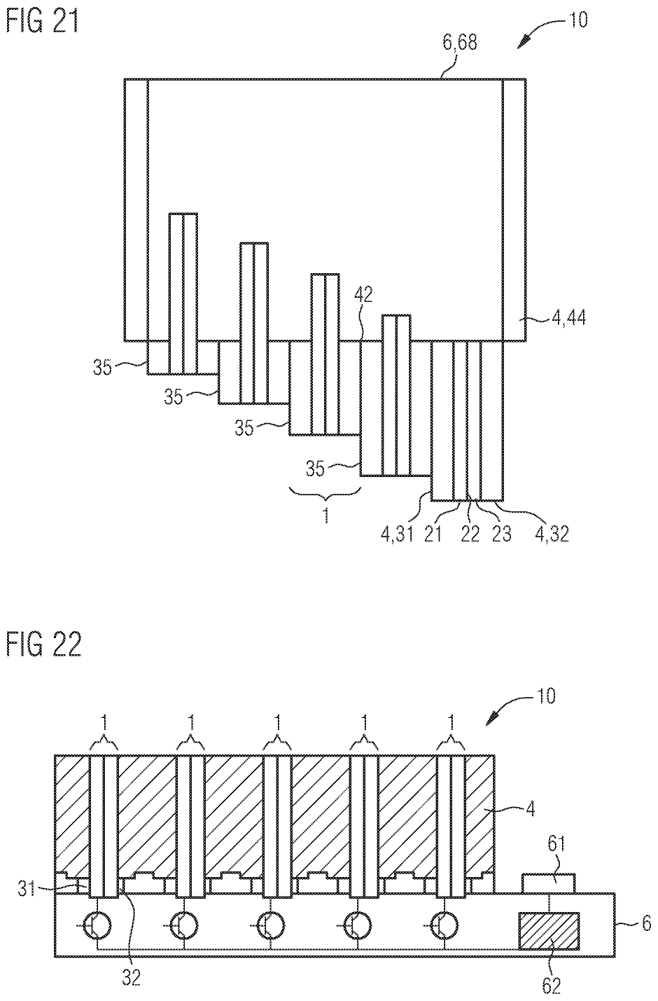

In the semiconductor device 10 of FIG. 21, the emitter units 1 are embedded in a potting body 68. In order to enable individual, external electrical contacting of the emitter units 1, the emitter units 1 can protrude to different extents or even completely from the potting body 68.

Optionally, an insulation layer 42 is located between adjacent emitter units 1 in each case to prevent electrical bridges. The light-transmitting potting body 68 forms the carrier 6 of the semiconductor device 10. A phosphor or an optical filter substance may be added to the potting body 68.

According to FIG. 22, the emitter units 1 are embedded in the reflector 4 formed as a potting body and attached to the carrier 6. It is possible that the electrical contact surfaces 31, 32 are only present close to the carrier 6. For example, in a direction away from the carrier 6, the emitter units 1 are covered by the contact surfaces 31, 32 to at most 50% or 25% or 10% of their length.

The carrier 6 is provided with contact points 61. Via the contact points 61, of which only one is drawn in FIG. 22, the carrier 6 can be connected to a data line for controlling the emitter units 1 and/or to a power supply, wherein wireless data transmission is also possible. Individual pixels 12 are individually controllable via drive electronics 62.

In FIG. 23 it is illustrated that the emitter units 1 are taken together to form RGB pixels 12. The emitter units 1, B and 1, G can be based on the material system InGaN and emit blue and green light directly from a semiconductor layer sequence. For the red emitting emitter units 1, R, the material system InGaN can also serve as a basis. In this case, the red light is generated by means of a phosphor, for example with GaN:Eu, which can be monolithically integrated in the emitter units 1, R.

According to FIG. 23, it is possible that the contact points are not located next to the emitter units 1 in plan view, but below them. The emission surface 11 can thus be completely formed by the emitter units 1 together with the reflector 4.

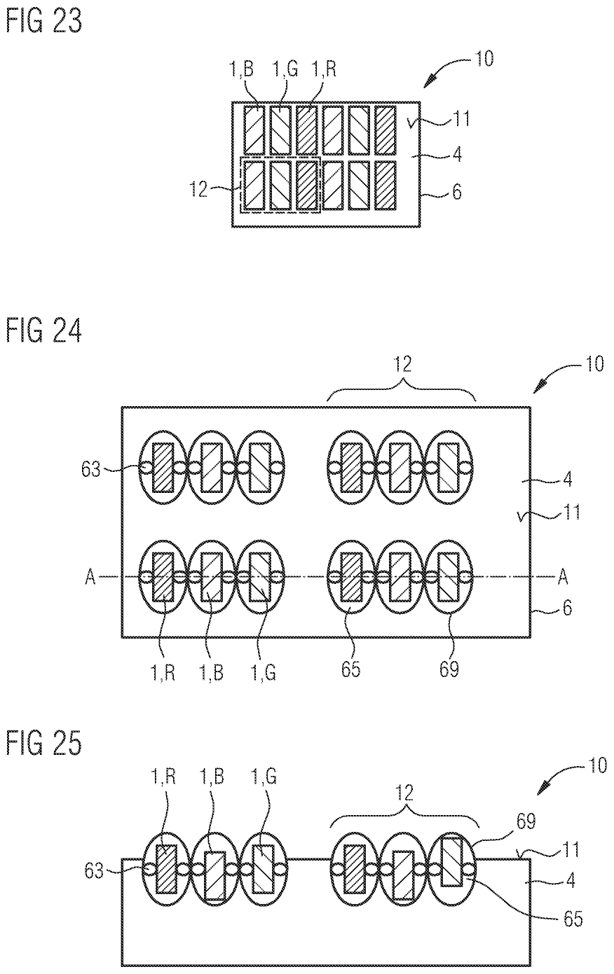

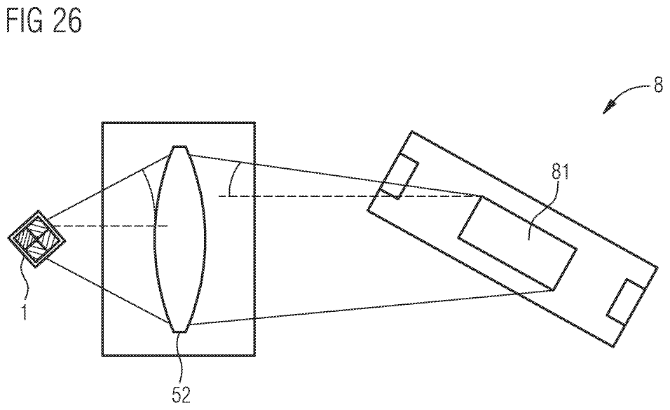

In the exemplary embodiment of FIGS. 24 and 25, the emitter units 1 grouped to form the pixels 12 are each located in a cavity 65. There may be a one-to-one correspondence between the cavities 65 and the emitter units 1. The emitter units 1 may also be tilted and spatially randomly arranged in the cavities 65, for example, when the emitter units 1 are mounted in the cavities 65 by means of pouring. That is, the emitter units 1 can be oriented differently relative to the reflector 4 and/or brought into the reflector 4 to different depths. In a non-limiting embodiment, there is nevertheless a clear color assignment of the emitter units 1 to the cavities 65.

It is possible that the emitter units 1 are arranged completely in the cavities 65 or that a small proportion of the emitter units 1 protrude from the cavities 65. An electrical contacting of the emitter units 1 in the cavities 65 is carried out by means of electrical connections 63, which can be located in each case on both sides of the emitter units 1 in or also on the cavities 65.

The emitter units 1 may be arranged at a distance from the reflector 4 in the cavities 65. It is possible that the cavities 65 are partially or completely filled with a filling 69, in which the emitter units 1 and optionally also the connections 63 can be embedded. Deviating from FIG. 25, it is possible that the emitter units 1 are not completely surrounded by the filling 69, but protrude from the filling 69.

FIG. 26 shows an exemplary embodiment of an illumination system 8. The illumination system 8 comprises one or also more of the semiconductor devices 1. Downstream of the at least one semiconductor device 1 is the focusing optics 52. The optics 52 is followed by a movable mirror 81 with a mirror surface. The movable mirror 81 is, for example, a digital micromirror device, or DMD. Thus, the illumination system 8 may be a Digital Light Processing device, or DLP for short. That is, the illumination system 8 may be a display. The optics 52 may be a micro lens device, or MLD for short.

In the illumination system 8, a maximum luminous area is limited in particular by the étandue of the optics 52 and/or the mirror surface. The semiconductor device 1 is for example composed of 4×299 μm RTTBs. The mirror 81 is, for example, a DMD, 0.199″ nHD.

For example, the semiconductor device 1 comprises an emission area of 0.41 mm². A mirror area of the mirror 81 is, for example, 12.16 mm². A half light collection angle of the optics 52 is, for example, 69°, and a half acceptance angle of the mirror 81 is, for example, 11.5°. This results in an Étandue of 1.25 mm² sr for the semiconductor device 1 and 1.81 mm² sr for the mirror 81.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

### REFERENCES

10 optoelectronic semiconductor device
1 emitter unit
11 emission surface
12 pixel
2 semiconductor layer sequence
21 n-type region
22 active zone
23 p-type region
24 first main side
25 second main side
26 side surface, covered by reflector
27 side surface configured for radiation emission
28 taper
29 tunnel junction
31 first electrical contact surface
32 second electrical contact surface
33 metallic layer
34 TCO contact layer
35 contact surface for external electrical contacting
36 intermediate layer
4 reflector
41 metal layer
42 electrical insulation layer
44 side part
51 roughening
52 optics
53 phosphor
6 carrier
61 contact point
62 drive electronic
63 electrical connection
64 cooling body
65 cavity
66 cooling component
68 potting body
69 filling
7 electrical insulating passivation layer
8 illumination system
81 movable mirror
9 modification
B base surface of the semiconductor device/emitter surface
E extraction efficiency
L length of the semiconductor layer sequence
R light
T thickness semiconductor layer sequence
W width semiconductor layer sequence
Z relative luminance density

1. An optoelectronic semiconductor device comprising:
at least one emitter unit; and
at least one reflector;
wherein:
the emitter unit comprises a semiconductor layer sequence having two mutually opposing main sides, a plurality of side surfaces, and an active zone configured to generate radiation,
the emitter unit comprises electrical contact surfaces located on the main sides; and
the reflector covers at least 90% of the main sides and all side surfaces except for a single side surface configured for radiation emission.

2. The optoelectronic semiconductor device according to claim 1,
wherein the contact surfaces cover each main surface directly by at least 90%,
wherein the contact surfaces each comprise at least one metallic layer and each form a part of the reflector, such that the reflector is an integral part of the associated emitter unit,
wherein a maximum distance of the reflector from the semiconductor layer sequence is at most 2 μm, and
wherein the side surface configured for radiation emission is free of the reflector.

3. The optoelectronic semiconductor device according to claim 1,
wherein a total thickness of the emitter unit is at most twice a thickness of an n-type region of the semiconductor layer sequence.

4. The optoelectronic semiconductor device according to claim 1,
wherein only the side surface configured for radiation emission comprises a roughening for increasing a light outcoupling efficiency.

5. The optoelectronic semiconductor device according to claim 1,
wherein the emitter unit comprises a plurality of the emitter units,
wherein the plurality of emitter units collectively form an emission surface composed of the side surfaces configured for radiation emission, and
wherein the plurality of emitter units are arranged in a linear arrangement or in a two-dimensional arrangement.

6. The optoelectronic semiconductor device according to claim 5,
wherein adjacent emitter units are successively arranged on their main surfaces, at least on opposite side surfaces not configured for radiation emission, or combinations thereof.

7. The optoelectronic semiconductor device according to claim 5,
wherein at least some of the emitter units are directly mechanically and electrically connected to one another via their contact surfaces.

8. The optoelectronic semiconductor device according to claim 5,
wherein the plurality of emitter units or groups of emitter units can be driven electrically independently of one another,
wherein emitter units emitting different colors are present.

9. The optoelectronic semiconductor device according to claim 5,
wherein at least one side part of the reflector is attached in common to all emitter units on the side surfaces not configured for radiation emission,
wherein the side part is diffusely reflecting and electrically insulating.

10. The optoelectronic semiconductor device according to claim 1,
wherein a number of the emitter units ranges from 300 to 30,000 inclusive,
wherein a thickness of the semiconductor layer sequence between the main sides ranges from 1 μm to 6 μm inclusive,
wherein a length of the semiconductor layer sequence in a direction perpendicular to the side surface configured for radiation emission ranges from 10 μm to 200 μm inclusive, and
wherein a width of the semiconductor layer sequence in a direction parallel to the side surface configured for radiation emission ranges from 30 μm to 1 mm inclusive, and the width is greater than the length.

11. The optoelectronic semiconductor device according to claim 1,
wherein the reflector is at least partly a metallic reflector or a metallic reflector in combination with at least one total internal reflection layer.

12. The optoelectronic semiconductor device according to claim 1,
wherein at least one side part of the reflector located at the side surfaces of the semiconductor layer sequence not configured for radiation emission is electrically separated from the contact surfaces.

13. The optoelectronic semiconductor device according to claim 1,
wherein at least one side part of the reflector located on the side surfaces of the semiconductor layer sequence not configured for radiation emission is electrically connected to one of the contact surfaces.

14. The optoelectronic semiconductor device according to claim 1,
wherein only one electrical insulation layer is located between the active zone and the reflector.

15. The optoelectronic semiconductor device according to claim 1,
further comprising at least one phosphor on the side surface configured for radiation emission,
wherein the semiconductor layer sequence of at least one emitter unit is based on AlInGaN and is configured to generate blue light.

16. The optoelectronic semiconductor device according to claim 1,
wherein the semiconductor layer sequence or the semiconductor layer sequence together with the contact surfaces is configured as an optical waveguide towards the side surface configured for radiation emission.

17. The optoelectronic semiconductor device according to claim 1,
wherein the semiconductor layer sequence tapers towards the side surface configured for radiation emission as seen in a plan view of one of the main sides, as seen in cross-section through the main sides, or combinations thereof.

18. The optoelectronic semiconductor device according to claim 1,
wherein the emitter unit is located in a cavity of the reflector or the emitter units are each arranged in their own cavity of the reflector, wherein the cavity or the cavities widen in a direction towards the side surface configured for radiation emission.
